(19) United States
(12) Patent Application Publication
(10) Pub. No.: US 2004/0005769 A1
(43) Pub. Date: Jan. 8, 2004

(54) Method and apparatus for endpoint detection

(75) Inventor: David G. Mikolas, Rowland Heights, CA (US)

Correspondence Address: Phyllis Turner-Brim, Cabot Microelectronics Corp., 870 Commons Drive, Aurora, IL, 60504, US

(73) Assignee: Cabot Microelectronics Corp.

(21) Appl. No.: 10/190,243

(22) Filed: Jul. 3, 2002

(51) Int. Cl. H01L 21/44; H01L 21/302; H01L 21/461

(52) U.S. Cl. 438/612

(57) ABSTRACT

This invention relates to methods of detecting a planarization endpoint in chemical mechanical planarization of a substrate wherein a detectable target is located at the endpoint and then detected during the CMP planarization. The invention also relates to layered substrates that contain a detectable target located between a first layer of material and a second layer of material. The invention also relates to methods of chemical mechanical planarization of a substrate.

### BACKGROUND OF THE INVENTION

1. Field of the Invention

This invention relates generally to methods of detecting a polishing or planarization endpoint in chemical mechanical planarization of a substrate. More particularly, the invention relates to methods of detecting a planarization endpoint by locating and detecting a target at or near an endpoint.

2. Description of the Related Art

Integrated circuits are made up of millions of active devices formed in or on a silicon substrate. Typically, an integrated circuit is formed on a substrate by the sequential deposition of conductive, semiconductive or insulative layers on a silicon wafer. After each layer is deposited, the layer is etched to create circuitry features. This fabrication process generally requires a subsequent layer to be deposited upon a smooth planar surface of a previous layer. However, the surface topography of layers may be uneven due to an uneven topography associated with an underlying layer. Therefore, a layer may need to be planarized in order to present a smooth planar surface for a subsequent processing step.

Chemical mechanical polishing (CMP) is one accepted method of planarization. In a typical chemical mechanical planarization process, the substrate is placed in direct contact with a moving polishing pad. A carrier applies pressure against the backside of the substrate. During the planarization process, the pad is moved while a downward force is maintained against the back of the stationary substrate. A chemically reactive solution is deposited onto the pad or onto the substrate during polishing. The solution initiates the polishing process by chemically reacting with the surface being planarized. An abrasive in the solution, in the polishing pad, or both removes a reacted surface film and exposes unreacted surface to further reaction. The chemically reactive solution also passivates the portions of the substrate that are not in contact with the pad thereby preventing unwanted etching. The planarization process is facilitated by the movement of the pad relative to the substrate as slurry is provided to the wafer/pad interface. Planarization is continued in this manner until the desired layer on the substrate is planarized or removed.

One problem associated with CMP is determining when the planarization endpoint is reached, i.e., whether the substrate surface has been planarized to a desired flatness or thickness or whether the surface material has been removed from the substrate. One approach to determining the planarization endpoint has been to remove the substrate from the polishing surface and examine it. If the substrate does not meet the desired specifications, it is reloaded into the CMP apparatus for further processing. If the examination reveals that an excess amount of material has been removed, the substrate is rendered unusable.

Several methods have been developed for in-situ planarization endpoint detection. Most of these methods involve monitoring a parameter associated with the substrate surface, and indicating an endpoint when the parameter abruptly changes. For example, where an insulative or dielectric layer is being planarized to expose an underlying metal layer, the coefficient of friction and the reflectivity of the substrate will change abruptly when the metal layer is exposed.

A problem associated with these methods is that as the substrate is being planarized, the polishing pad condition and the slurry composition at the pad-substrate interface are changing. Such changes may mask the exposure of an underlying layer, or they may imitate an endpoint condition. Additionally, endpoint detection methods that identify the exposure of a new material layer do not work when removal of material does not expose a different material, if only removal of a portion of a uniform layer is being performed, if the underlying layer is to be over-polished, or if the underlying layer and the overlying layer have similar physical properties.

Accordingly, there is a need for planarization endpoint detectors that accurately and reliably indicate when the planarization process is complete.

### SUMMARY OF THE INVENTION

One aspect of this invention are methods for detecting the endpoint of the chemical mechanical planarization of a substrate having a first layer of material and a second layer of material, wherein the second layer of material has an exposed surface that is planarized. The method includes steps comprising: placing a target at or near a location between the first layer of material and the second layer of material; planarizing the second layer of material to remove at least a portion of material from the layer; detecting the target; and adjusting the planarizing step in response to detecting the target.

Another aspect of this invention are chemical mechanical planarization methods comprising: placing the substrate in contact with a rotating pad, wherein the substrate comprises a first layer of material, a second layer of material and a target placed at or near a location between the first and second layers of material; applying pressure against the backside of the wafer; causing relative motion between the substrate and the pad; depositing a polishing composition onto the pad; planarizing the wafer by removing material from the second layer; and adjusting the planarization step in response to detecting the target.

Still another aspect of this invention are substrates comprising a first layer of material, a second layer of material and a target placed at or near a location between the first and second layers of material.

The endpoint detection methods, systems and substrates disclosed herein provide several advantages over prior art detectors. For example, the systems of the present invention can utilize multiple targets to provide increased accuracy. The targets can possess different properties thus warning of the approach of different events, such as layer breakthrough. The data collected may be in the form of a count rate above a certain threshold, thus it is simple to process and there is no spectral analysis required for the data. The targets of the invention are compatible with VLSI (very large scale fabrication). Endpointing is measured in real time while the wafer is in motion thus providing virtually instanteous feedback. The optics used for detection of signals can be very small in size thus facilitating incorporation of the system into a planarization machine. The targets used are compatible with various substrate layers, including metals and oxides.

### BRIEF DESCRIPTION OF THE DRAWINGS

FIG. 1 is a schematic cross sectional view of a segment of a substrate during processing including an optically detectable grating embodiment.

FIGS. 2A and B shows the use of a third layer of material between a first layer and a second layer of material in a periodic grating.

FIG. 3 is a graph of detection rate versus CMP process time for a system using two gratings.

FIG. 4 is a grating having two different pitches and located between a first and second layer of material.

FIGS. 5 is a cross sectional view of a segment of a substrate of this invention containing a fluorescent layer and the various steps of a CMP process.

FIG. 6 represents an optical detection system that can be used in the invention.

FIG. 7 represents an optical detection system that can be used in the invention.

FIG. 8 represents an optical detection system that can be used in the invention.

FIG. 9 is a graph of detection rate versus CMP process time for a simulation of endpointing with a multi grating target system.

FIG. 10 is a graph of detection rate versus CMP process time for a system using half wave and quarter wave gratings.

FIG. 11 represents examples of half wave and quarter wave grating structures that can be used in the invention.

### DESCRIPTION OF THE CURRENT EMBODIMENT

As used in this specification, the terms “substrate” and “wafer” refer to various substrates including micro-fabricated structures such as integrated circuits, photonic light circuits, micro-fluidic, micro-mechanical, micro-opto-mechanical (MEMS/MEOMS) or other structures, where manufacture includes the application of one layer to another. The terms refer to both finished and unfinished articles.

As used in this specification, the term “layer” refers to any of the layers of a substrate. For example, the term “layer” includes layers of materials such as dielectrics, metals, semiconductors, adhesives and polymers for applications required for device function as well as adhesion, support, thermal heat-sinking, passivation, hermtec seal, and layers associated with optical, electrical or any other type of interconnect.

As used in this specification, the terms “first layer” and “second layer” refer to layers that are applied one over the other. The “first layer” and the “second layer” can be the same materials or they can be different materials, including layers of the same type but of different material. For example, a “first layer” and a “second layer” can both be dielectric layers of different materials. Alternatively, as an example, a “first layer” and a “second layer” can both be dielectric layers fabricated of the same dielectric material.

As used in this specification, the phrase “location between the first layer and the second layer” describes the interface in a substrate where a first layer of material meets an adjacent second layer of material. This location can simply be the position in the layer where a target is placed or patterned. For example, if a first layer of dielectric material is deposited on the substrate, and the deposition paused or adjusted to allow for placement of a target, and then deposition of the first layer is continued, the target is considered to be at a location between the “two” layers. Similarly, if a first layer of material is deposited on a substrate, and a target is then placed, and then a second layer deposited, the target is considered to be at a location between the “first layer and the second layer” or between the “two” layers.

As used in this specification, the term “a target” refers to one or more structures that can be detected by a detection system. In one embodiment, the target is one or more line-space patterns, such as a periodic grating, that diffract light in a predictable manner. In another embodiment, the target is a compound or compounds that undergo a detectable change in response to light, such as fluorescent, phosphorescent, and/or other energy absorbing compounds. These compounds are herein referred to as spectrally active materials. Preferably, the target is one or more periodic gratings, or fluorescent or absorbing compounds, or a combination thereof.

As used in this specification, the phrases “detecting the target” and “observing the target” are used interchangeably and include detecting or observing the presence or absence or removal of the target, or detecting or observing the partial presence or partial removal or partial absence of the target within a well defined “field of view” determined by the light collection optics. The degree of presence or absence of the target is determined from an interpretation of the instantaneous optical intensity of the diffracted light level as the target passes through the field of view.

One aspect of this invention are methods for detecting the endpoint of chemical mechanical planarization of a substrate having a first layer of material and a second layer of material, wherein the second layer of material has an exposed surface that is planarized. The endpoint detection method includes placing a target at or near a location between the first layer of material and the second layer of material; planarizing the second layer of material to remove at least a portion of material from the second layer; detecting the target; and adjusting the planarizing step when the target is detected. In one embodiment of this aspect of the invention, the target is a periodic grating. In another embodiment, the target is a spectrally active material. Each of these embodiments is described in detail below.

In another aspect, this invention is directed to a method of chemical mechanical planarization of a substrate, comprising: placing the substrate in contact with a polishing pad, wherein the substrate comprises a first layer of material, a second layer of material and a target placed at or near a location between the first layer of material and the second layer of material; applying pressure against the backside of the wafer; causing relative motion between the substrate and the pad; depositing a polishing composition onto the pad; planarizing the wafer by removing material from the second layer; and adjusting the planarization step when the target is detected.

In a typical chemical mechanical polishing (CMP) process, the substrate surface that is being polished is placed into contact with a rotating polishing pad. A carrier applies pressure against the backside of the substrate. During the polishing process, the pad and/or table are rotated while a downward force is maintained against the substrate back. A polishing composition is applied to the interface between the polishing pad and the substrate surface being polished. The polishing composition can be applied to the interface by applying the polishing composition to the polishing pad surface, to the substrate surface being polished or both. The polishing composition can be applied to the interface either intermittently or continuously and the application of the polishing composition can begin prior to or after the polishing pad is brought into contact with the substrate surface being polished. Finally, the term “applying a polishing composition” as it used in the specification and claims is not time limited and refers to the application of a polishing composition either before or after a polishing substrate is moved into contact with the surface being polished.

The polishing process further requires an abrasive material to assist in removing a portion of the substrate surface that has been softened by a reaction between the polishing composition and the substrate surface material. The abrasive may be incorporated into the polishing pad such as polishing pads disclosed in U.S. Pat. No. 6,121,143 which is incorporated herein by reference, it may be incorporated into the polishing composition, or both. Ingredients in the polishing composition or slurry initiate the polishing process by chemically reacting with the material on the surface of the substrate that is being polished. The polishing process is facilitated by the movement of the pad relative to the substrate as the chemically reactive polishing composition or slurry is provided to the substrate/pad interface. Polishing is continued in this manner until the desired film or amount of film on the substrate surface is removed.

The movement of the polishing pad in relationship to the substrate can vary depending upon the desired polishing end results. Often, the polishing pad substrate is rotated while the substrate being polished remains stationary. Alternatively, the polishing pad and the substrate being polished can both move with respect to the polishing equipment. The polishing substrates and in particular the polishing pads of this invention can be moved in a linear manner, they can move in a orbital or a rotational manner or they can move in a combination of the directions.

The polishing pad can optionally contain a window that is transparent to the light beam of the detector, thereby facilitating detection of the target at the endpoint. Such polishing pads are well known in the art. For example, U.S. Pat. No. 6,296,548, which is herein incorporated by reference in its entirety, describes a polishing pad with a window.

The polishing composition is formulated to include chemicals that react with and soften the surface of the material being polished. Depending on the choice of ingredients such as oxidizing agents, film forming agents, acids, bases, surfactants, complexing agents, abrasives, and other useful additives, the polishing slurry can be tailored to provide effective polishing of the substrate layer(s) at desired polishing rates while minimizing surface imperfections, defects and corrosion and erosion. Furthermore, the polishing composition may be selected to provide controlled polishing selectivities to other thin-film materials used in substrate manufacturing.

Examples of useful CMP polishing compositions and slurries are disclosed, in U.S. Pat. Nos. 6,068,787, 6,063,306, 6,033,596, 6,039,891, 6,015,506, 5,954,997, 5,993,686, 5,783,489, 5,244,523, 5,209,816, 5,340,370, 4,789,648, 5,391,258, 5,476,606, 5,527,423, 5,354,490, 5,157,876, 5,137,544, 4,956,313, the specifications of each of which are incorporated herein by reference.

This invention also relates to substrates comprising a first layer of material, a second layer of material and a target placed at or near a location between the first and second layers of material.

The target used in the invention is any detectable structure that can be detected at its location by a suitable detection system. For example, the target can be a line space pattern that diffracts light in a predictable manner, such as a periodic grating, or it can be a hologram or it can be a spectrally active material, or combinations thereof. Preferably, the target is a periodic grating or a spectrally active material.

Periodic Grating Target

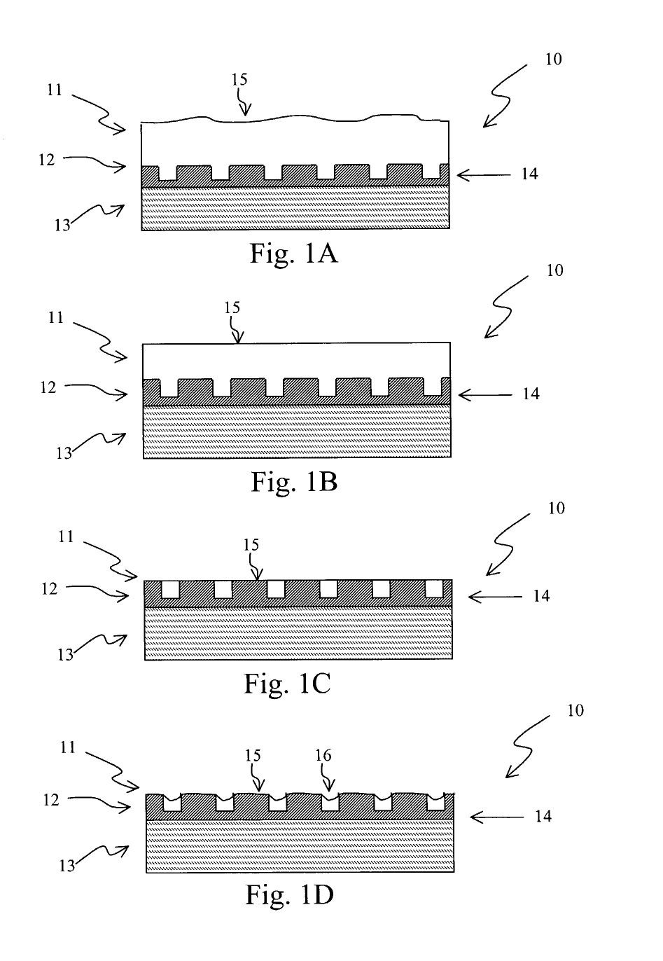

In one embodiment the target used in the various aspects of the invention is at least one periodic grating. The periodic grating is placed at or near a location between a first layer of material and a second layer of material. This embodiment is illustrated in FIGS. 1A-1D.

Referring now to FIGS. 1A-1D, there is shown a cross-sectional view of a segment of a substrate (10) including a grating pattern (14) during various steps of a process according to the present invention. FIG. 1A shows a substrate having a bottom layer (13), a first layer of material (12), a grating pattern (14) etched into the first layer of material (12), and a second layer of material (11) having a top surface (15). As shown in FIG. 1A, the optical grating is optionally located between first layer (12) and second layer (11).

In the embodiment shown in FIG. 1, first and second layers (12, 11) preferably have different planarization removal rates. This difference in removal rates results in dishing of the top layer during planarization. If first layer (12) and second layer (11) of FIG. 1A are dielectric materials with substantially the same indices of refraction, then the indices of refraction of the dielectric layers should be different from that of the CMP slurry itself. If all three materials had the same indices of refraction, then there would be no observable optical effect and no optical signal would be generated. Alternatively, the CMP slurry can have substantially the same index of refraction as one of the layers, provided that the index of refraction of the other layer is substantially different from the first layer and the CMP slurry, thus providing an observable optical effect.

In the fabrication of the substrate depicted in FIG. 1, first layer (12) is deposited and periodic grating (14) is patterned into it. Then second layer (11) is deposited thus filling up the pattern of the grating. Initially, there may be a slight residual periodicity on the surface (15) of second layer (11), however, once planarization of the surface is begun this residual periodicity disappears and there is little or no optically detectable periodic pattern on the surface related to the grating topography.

Chemical mechanical planarization of the uneven top surface (15) of the second layer (11) results in a planar top surface (15), as shown in FIG. 1B, in which the grating is either optically invisible (if the indices of refraction of the layers are essentially equal) or is visible but does not change during the planarization step. Continued planarization of the second layer (11) results in almost complete removal of the second layer (11), as shown in FIG. 1C.

Further planarization results in additional removal of the top layer and formation of a wash board topography produced by short range dishing (16), resulting from the different rates at which the first and second materials are removed from the substrate by CMP, as discussed above and as shown in FIG. 1D. Detection of this topography and, therefore, the proximity of the endpoint, is achieved using laser light or other quasi chromatic light of sufficient intensity, which will diffract off the exposed topography pattern in a predictable pattern. An optical identification apparatus such as a light collection system and a detector is programmed or tuned to be sensitive for the particular pitch or pattern reflecting off the topography and detects the presence or absence of the grating.

For simplicity, the above description is presented in terms of one grating between two layers. The invention is, however, not limited to the use of one grating, and the use of several gratings on a substrate is contemplated.

In fact, one of the advantages of the present invention is that the use of multiple targets permits the simultaneous monitoring of different regions of a substrate during planarization. This is achieved, for example, by using multiple periodic gratings, as the target having different distinguishable characteristics, such as different pitch or different orientation, and a detection system tuned to these characteristics. For instance, a first grating with a first detectable characteristic is placed in a first region of the substrate and a second grating, with a second detectable characteristic is placed in a second region of the substrate. During planarization an operator can, by monitoring the first or second grating, determine when the first or second region has been reached. As a result, the endpointing curves for the two regions can be detected or monitored simultaneously. This technique is particularly applicable where the two regions of the substrate planarize at different rates, for example, because one region has a high pattern density and the other region has a lower pattern density. The technique is not limited to two gratings or two regions and is equally applicable to multiple targets having multiple characteristics and placed in multiple regions.

A further application of the use of gratings with different observable characteristics is that the gratings can be used to signal events other than or in addition to layer breakthrough, during planarization. Thus a grating with a specific observable characteristic is encoded for the particular event of interest. For example, a grating with a first pitch size can be encoded, for instance, for extra thin films or certain material types and placed in proximity to those regions, and a grating of a second pitch size can be encoded, for instance, for a specific pattern density or specific locations in a die or substrate, and placed in proximity to that event. During planarization, observation of a grating with a particular characteristic (such as the first or second pitch size in the above example) indicates the event for which the grating is encoded. The planarization process can then be adjusted as required. Clearly, in the various embodiments of the invention, it is not required that the grating be placed adjacent to two different layers of material, since the grating can be used to indicate the presence of a specific event as described above, and not necessarily the clearing or removal of a material layer.

Preferred distinguishable characteristics between two gratings include differences in the pitches of the gratings or the orientations of the gratings. Where the distinguishable characteristic is pitch size, the gratings have different pitch sizes that are in the range of about 0.5 microns to about 3 microns. Where the distinguishable characteristic is orientation, the gratings are preferably oriented by about 10 degrees to about 180 degrees, preferably 90 degrees, relative to each other.

The gratings of the invention can be patterned at the desired location by various methods including etching, index modification, deposition, and by shallow trench isolation (STI) processes. These and other techniques are well known in the art and are described, for instance, in Kirk Othmer Encyclopedia of Chemical Technology, 4th Edition, vol. 14, John Wiley & Sons, New York, 1995, page 766, which is herein incorporated by reference.

In a typical etching process, the periodic grating can be patterned into a layer of material either as a negative structure, by etching trenches of the appropriate dimensions into the layer, or as a positive structure, by building up additional material to make the pattern.

As an example, an etching process may include the following steps. A standard photolithographic deposition (e.g., by chemical vapor deposition) of a first layer of resist is conducted. One or more periodic gratings with the desired periodicity are then etched or ablated into the layer, for example, by reactive ion etching, ion beam sputter, or wet chemical etch. A second layer of material is deposited over the first layer thus filling in the grating patterns. Additional grating patterns can be added to the second layer, or additional layers deposited.

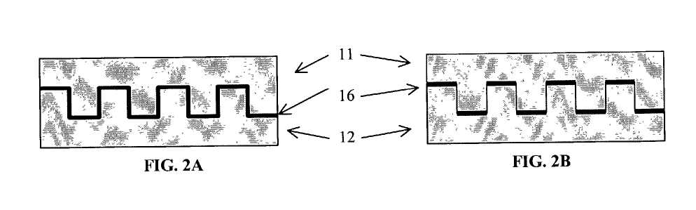

As a modification to the etching processes, a thin layer of a third material can be deposited on the first layer after etching of the grating. This third material (16 in FIG. 2) can be deposited to either conform to the grating pattern (see FIG. 2A) or as a directional sputter or evaporation (see FIG. 2B). Optionally third layer (16) may be highly reflective in order to provide the difference in indices of diffraction necessary for observance of an optical effect, as discussed above. For example, the layer can be of very high index of refraction (e.g., amorphous silicon or other semiconductors) or can be highly reflective (e.g., a metal).

If two adjacent material layers (for example, (11) and (12) in FIG. 1) possess substantially the same indices of refraction and CMP removal rates, then it will be difficult to observe a periodic grating structure located between them. To overcome this problem, a third material having different CMP removal rate from the other layers, can be used to fill the trenches of the patterned grating. The difference in CMP removal rate will cause dishing to occur in the surface of the top layer during the planarization, allowing for diffraction of light off the dishing pattern, and detection of the target grating.

An alternative technique for positioning a grating on a layer is through index modification. In an index modification process, the grating pattern is prepared by masking and selectively exposing the dielectric layer on which the grating is to be patterned to external factors such as radiation, dopants, or implantation of ions. The selective modification of the layer results in modification of the index of refraction of the exposed areas in the shape of the grating thus permitting diffraction of incident light and detection of the target.

The size of the optical gratings of the invention depends, in part, on the characteristics and dimensions of the substrate. Generally, the size ranges from about 50 μm by 50 μm to about 1000 μm by 1000 μm (width by length), and ranges therebetween. Preferably, the grating is 50 μm by 100 μm.

The depth of the trenches of the patterned grating depends, in part, on the wavelength of light being used to diffract off the grating. Generally, the depth of the trenches is about one eighth of the wavelength of the light. For example, if a 450 nm blue laser is used, the depth of the trenches is about 50 nm. Preferably, the depth is within the range of about 30 nm to about 300 nm.

The pitch of the gratings can vary, again depending, for example, on the wavelength of light to be diffracted. Generally, the pitch necessary to provide diffraction from a particular wavelength of light can be calculated from the following equation (1):

SIN(θ2)−SIN(θ1)=m*lambda/d (1)

Where θ2 is the angle of refraction of an outgoing ray of light, and 01 is the angle of incidence of an incoming ray of light, m is the desired order of diffraction, lambda is the wavelength in the medium through which the light passes and d is the period of the grating. The angle of refraction, θ2, is generally between about 5 degrees and 40 degrees, typically 20 degrees, from the normal plane. Lambda in equation (1) is calculated by dividing the wavelength of the light in a vacuum by the index of refraction of the material through which the light passes (lambda=lambda_vac/n, where n is the index of refraction).

For incidence at the normal plane (θ1=0) equation (1) reduces to equation (2):

d=m*lambda/SIN(θ2) (2)

There is no particular limitation on the wavelength or nature of the light that is used for diffraction. Many different wavelengths are suitable. In addition, the light source can be a mixture of wavelengths. Wavelengths that can be used include, but are not limited to, 450 nm Blue Ar+ Laser, 650 nm Red HeNe or GaAs-based laser, 850 nm GaAs based laser diode, 1064 nm Nd YAG Solid State Laser, 1500 nm InP based laser diode, or mixtures thereof.

As an example, assuming the average index of refraction, n, of the medium (e.g., the aqueous base solutions, dielectrics, etc.) is 1.5, and that the detector is placed to collect refracted light at an angle of 20 degrees (θ2=20), then the feature size (half period) of the grating that should be used for various wavelengths of light is approximately as follows. For 450 nm Blue; feature size of the grating is approximately 0.3 to 0.5 microns. For a red laser such as a HeNe gas laser or (In)GaAsP semiconductor laser around 650 nm; feature size of the grating is approximately 0.5 to 0.7 microns. For an AlGaAs based semiconductor laser around 850 nm, feature size of the grating is approximately 0.7 to 0.9 microns. For a 1064 nm Nd: YAG Solid State Laser; feature size of the grating is approximately 0.9 to 1.1 microns. For an InP based semiconductor laser around 1.55 microns; feature size of the grating is approximately 1.35 to 1.55 microns.

As discussed above, the use of multiple gratings on a substrate with different optical characteristics that are distinguishable by a detection system is one feature of the present invention. Easily distinguishable optical characteristics include the period of a grating, the pitch of a grating, the depth of the grating trench, or the orientation of the grating, as well as the intensity of the diffracted signal. Thus, the endpointing curves for two different regions that include gratings with different characteristics can be detected simultaneously. For example, a first grating with one characteristic can be used in an area of high pattern density, and a second grating with a different characteristic can be used in an area of low pattern density, thus permitting an operator to monitor the polishing of the two areas. Alternatively, one grating type could be used to signify the approach of an endpoint and another grating type used to signify the actual endpoint.

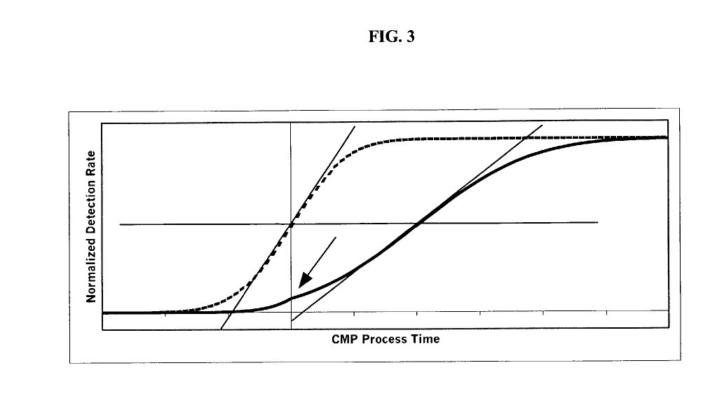

FIG. 3 is a graph representing the use of two gratings at different depths (such as the type shown in FIG. 1 having substantially equal indices of refraction of the two layers (11 and 12)). The dotted line corresponds to the signal from the higher target which is observed first during the CMP process. Once the CMP tool reaches endpoint criterion with the first grating (in this example endpoint criterion is set at 50% signal level) the CMP tool can be triggered to change a polishing parameter such as down-force or any other parameter that decreases removal rate without decreasing average wafer velocity. The arrow indicates a slope change in the solid curve (lower target) showing the slow-down in removal rate. By decreasing this rate but not decreasing the rate of target detections per second, better statistical averaging is possible and more precise endpointing on the lower mark (solid line) is possible.

The substrate can also contain more than one grating and/or grating type at the same interface. The number and placement of gratings on a wafer is determined by the specific needs of a given application and is determined primarily by the required reproducibility in endpoint detection. The more gratings scanned per unit thickness removed, the better the statistical averaging. An example of endpointing using a multiple grating target is presented in Example 1 below.

The number of targets crossing the field of view of the detector can be calculated as follows. If d is the characteristic size of the field of view of the device; Vₐᵥₑ is the average speed of the wafer surface across the field of view; A_{waf} is total area of wafer where devices are measured; n_{pdie} is number of gratings per die; n_{gdic} is the number of good “active” die per wafer which contain gratings; and f_{waf} is the fraction of the time that field of view falls anywhere on a wafer, then the following parameters can be calculated.

The average area that the field of view of the device sweeps out over any part of the wafer per unit time is given by

d Vₐᵥₑ f_{waf}

and the number of good gratings per unit are on the wafer is

n_{pdie}/n_{gdie}/A_{waf}

The number of gratings per unit time crossing the field of view is then approximately

d vₐᵥₑf_{waf}n_{pdie}n_{gdie}/A_{waf}

Spectrally Active Material Target

In another embodiment, the target used in the various aspects of this invention is a spectrally active material. Spectral activity includes, but is not limited to, fluorescence, phosphorescence, and energy absorption and transient bleaching of the light-absorbing species which can then be measured by pulse-probe techniques. Classes of spectrally active materials that can be used in this embodiment of the invention include inorganic atomic species such as lanthanides, and organic dyes and chromophors. The preferred spectral activity is fluorescence. The preferred class of spectrally active fluorescent compounds are the atomic lanthanides. Examples of preferred lanthanides are Eu³⁺ and Er³⁺ producing light around 650 nm and 1.5 microns, respectively. The light used to induce fluorescence of these species can be pulsed or modulated at high frequency. Trivalent lanthanides typically have a decay half-life of a microsecond to ten milliseconds which would be of a shorter wavelength (higher energy) than the fluorescence wavelength, and could be introduced into the optical field of view by application of a dichroic mirror.

The fluorescent material used in this embodiment of the invention is of the correct valence state to fluoresce while in the wafer and is protected in the oxide matrix from collisions so that it can hold excitation long enough to de-excite radiatively while on the wafer. However, once the fluorescent material enters the slurry, its chemical form and/or its valence state changes and it ceases to fluoresce. Alternatively, the simple washing away and dilution of the fluorescent material may stop or reduce its fluorescent signal.

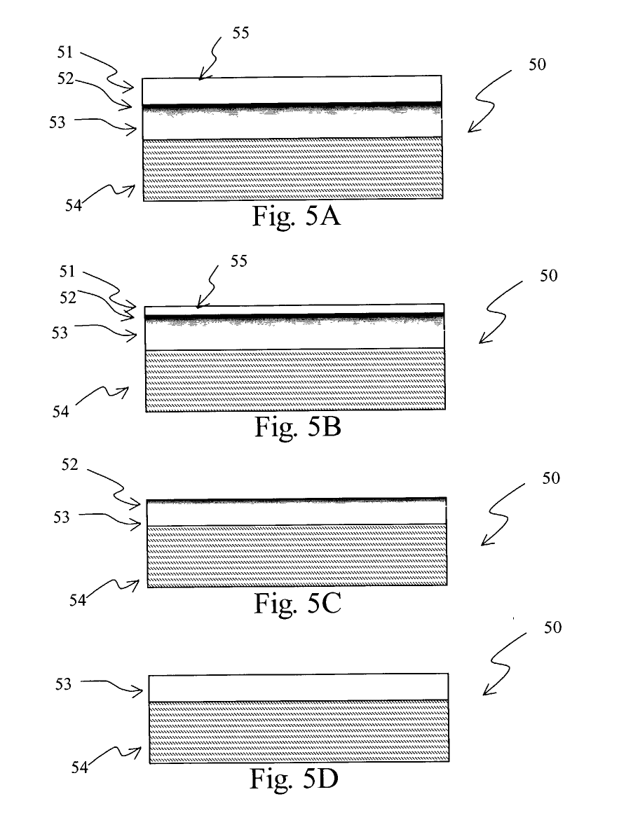

FIGS. 5A-5D represent an example of the embodiment of the invention where the target is a spectrally active material. Referring now to the FIGS. 5A-5D, there is shown a cross-sectional view of a segment of a substrate (50), including a fluorescent material layer, after various steps of a fabrication process according to the present invention. FIG. 5A depicts a substrate having a lower layer (54), a first layer of material (53), an endpoint layer comprising a fluorescent material (52), a second layer of material (51), and a top surface (55). Lower layer (54) maybe a deposited layer or it maybe the base substrate of the wafer, such as silicon in an integrated circuit. Chemical mechanical planarization of top surface (55) is conducted while the level of fluorescence from the wafer is measured. Continued planarization of top surface (55) removes material from second layer (51), as shown in FIG. 5B, until the endpoint layer is reached, at which point the removal of the fluorescent material from the wafer into the slurry begins. As this occurs, the level of fluorescence from the wafer is reduced, indicating that the endpoint is close or has been reached. A partially removed endpoint layer is depicted in FIG. 5C. Continued planarization results in complete removal of the target layer, as shown in FIG. 5D, and the cessation of fluorescence from the wafer. A fluorescence detector continuously or intermittently detects the reduction or cessation of fluorescence from the wafer as the fluorescent material is removed from the wafer into the slurry solution.

Methods of depositing a layer of material, such as a spectrally active compound, are well known in the art. Such methods include, for example, atmospheric pressure chemical vapor deposition (APCVD), low pressure chemical vapor deposition (LPCVD), or plasma enhanced chemical vapor deposition (PECVD).

As an example of a process for incorporating a spectrally active material (endpoint layer) into a substrate, a dielectric film deposition is either stopped or paused at the point where the endpoint layer is to be deposited. At this point, the dielectric is doped with spectrally active material and deposition with the doped dielectric is continued to provide an endpoint layer. Deposition is then continued either with the doped dielectric or with undoped dielectric.

Alternatively, the first (lower) layer of material is doped with a spectrally active material, but the second (upper) layer is not. Detection of spectral activity, such as fluorescence, from the substrate during planarization of the second layer reveals the approach or presence of the first layer which contains the spectrally active compound.

As a further alternative, the second (upper) layer is doped with the spectrally active material, but the first (lower) layer is not. Cessation of spectral activity from the substrate during planarization indicates removal of the second layer containing the spectrally active material.

Detection Systems

Detection systems and associated optical systems for detecting the various targets of the invention are well known in the art. For example, detection systems for detecting fluorescent compounds are described in U.S. Pat. Nos. 6,317,206, 6,310,352, 6,303,929, 6,297,509, 4,202,491, each of which is herein incorporated by reference in its entirety.

When the target used in the various aspects of the invention is a periodic grating, the detection system preferably measures the spatial Fourier transform of the field of view and expresses this as a pattern on a focal plane, where, expressed in radial coordinates, the radius corresponds to the wave-number (inverse pitch) and the azimuthal coordinate corresponds to the orientation of that pitch. A few non-limiting examples of various optical systems for use in the detection systems are discussed below.

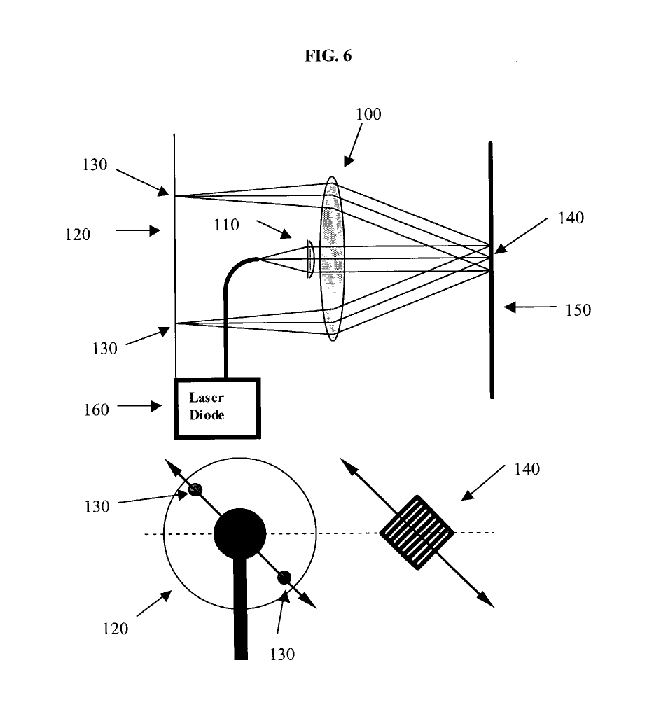

The first example is a straightforward implementation of a spatial Fourier transform function and is illustrated in FIG. 6. Shown are a primary lens (100), a collimating lens (110), an output plane (120) having first order diffraction points (130), a periodic grating aligned with the first order diffraction points (140), a substrate (150), and laser diode (160) as the light source. The primary lens performs a spatial Fourier transform converting a spatially periodic pattern present anywhere within the field of view of the lens into a set of spots at the output plane, whose location indicates the period and orientation of the grating. The pattern on the output plane remains essentially constant and stable while the target moves across the field of view of the lens. Rotation of the wafer with respect to the field of view will however result in the rotation of the spots by the same angle. The gratings are illuminated by an expanded, collimated beam. The physical size of the emission source is transferred to the physical size of the spot at the output plane for an ideal system.

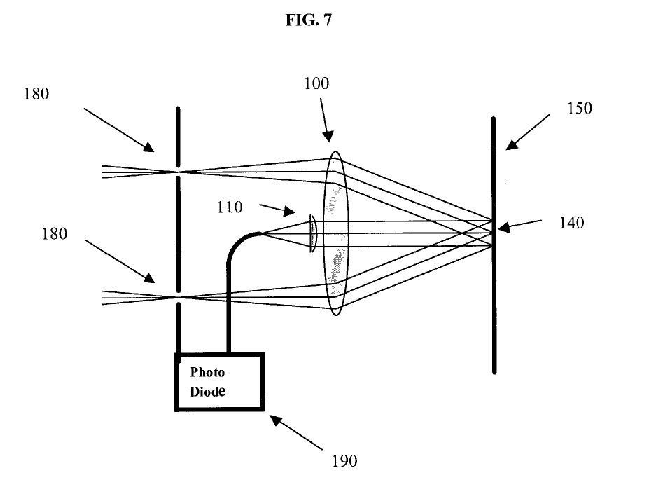

Another example of an optical system that can be used in the invention is illustrated in FIG. 7. The direction of the light is reversed relative to the first example and the light is tuned to a specific pitch. The detector is set on-axis, thus detecting diffracted light only when the proper pitch is present. An annular source of light illuminates the gratings (140) on the substrate (150) through an order defining aperture (180). If a grating with a pitch corresponding to the tuned wavelength of the light passes through the field of view of the lens, the diffracted light is directed back at 0 degrees into the detector (190) and detected.

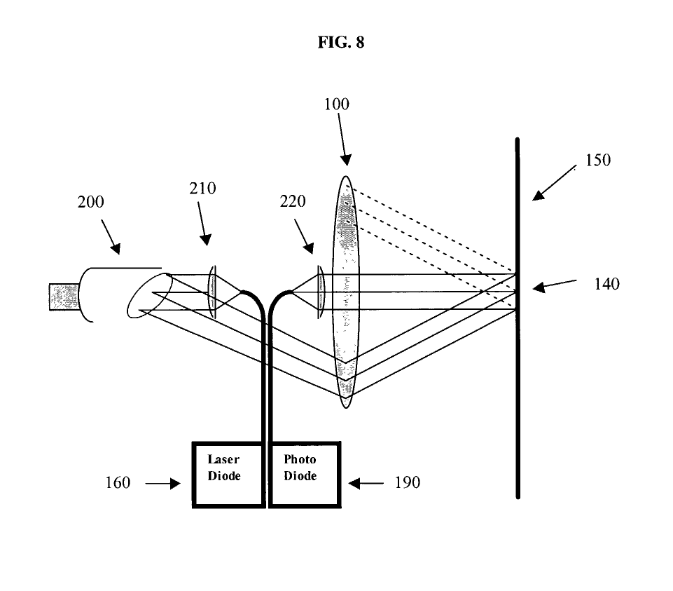

In a third example, illustrated in FIG. 8, a rapidly cycling scanning system periodically covers azimuthal angles and radii over a large range. At the moment when the on-axis detector detects a signal, the instantaneous orientation of the scanning system indicates the exact pitch and orientation of the object. This technique is the most powerful as it can detect multiple gratings having distinguishable and observable characteristics, such as differing pitches or orientations, simultaneously. Shown in FIG. 8 are the components of this optical system: a scanning mirror (200), laser diode collimator (210), photo diode collimator (220), primary lens (100), substrate (150), grating (140), laser diode (160) and photo diode detector (190).

The optical system shown in FIG. 8 provides excellent selectivity for angle or orientation and pitch, and permits for the constant measurement of the presence of gratings at all pitch and/or orientation combinations. Because the system can detect the exact pitch and orientation of a diffracting object, it can sense the orientation of the underlying circuitry and other patterns and thus instantly reject false positives.

The following examples are illustrative of various aspects of the invention but do not serve to limit its scope.

### EXAMPLES

### Example 1

### Simulation of Endpointing With a Multi-Grating Target

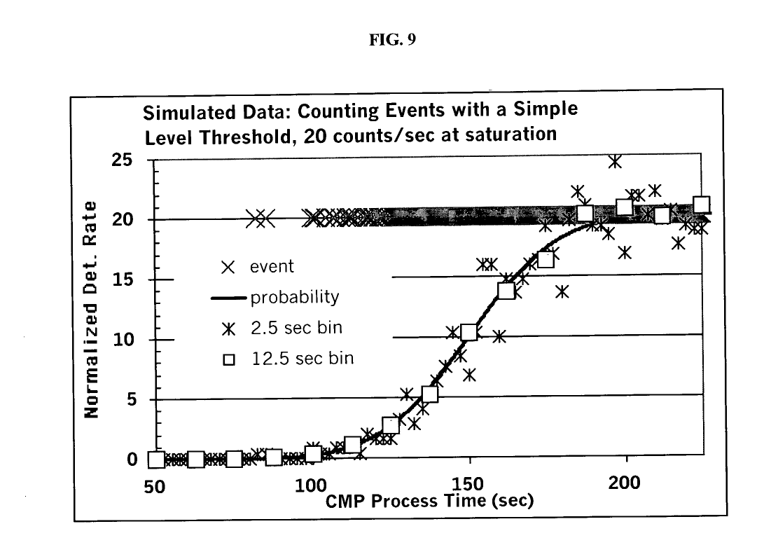

A graphical simulation of the detection of multiple gratings passing a field of view of a diffraction detector is show in FIG. 9. The simulation assumes that a given grating makes a sudden change from invisible to visible when it is exposed during CMP, and assumes an approximately gaussian distribution in CMP removal rate errors across the wafer. Each cross indicates the detection of one grating. In the simulation, detection of the gratings does not begin to happen until about 100 seconds of processing. Grating detections continue to increase in frequency until about 180 seconds of processing. The smooth solid line indicates the average behavior of the detected events when a very large number of independent wafers is measured and the data averaged.

The symbols labeled “2.5 sec bin” represent binned averages of the count rate over 2.5 second intervals (i.e., the number of targets detected in a 2.5 second window), and the symbols labeled “12.5 sec bin” are binned over consecutive 12.5 second intervals. As expected, the longer bin size shows a decreased statistical fluctuation. It is possible to estimate from the graph that, if a count rate maximum is determined ahead of time, then the 50% count rate point could be detected with perhaps +/−10 seconds precision, or about +/−7% of the average thickness removed using the 2.5 second bins. If the 12.5 second bins are used, a smaller uncertainty in time results even thought the bin is 5 times longer.

The detection precision can be improved in a number of ways, for example, as follows:

1) Decrease the CMP removal rate. The number of counts per second remains the same at a given depth, but the thickness changes more slowly, allowing more time for averaging.

2) Add more targets;

3) Use a functional form, such as an Error Function for example, to fit the data, extrapolating or interpolating to find the 50% crossing point;

4) Use marks with higher “contrast” that change from “undetected” to “detected” with a smaller amount of material removed. One example would be a thin (100-300 micron), very dark or highly reflective deposited layer of metal or high index semiconductor (e.g., Si, Ge).

### Example 2

### Target Construction and Resulting Signals

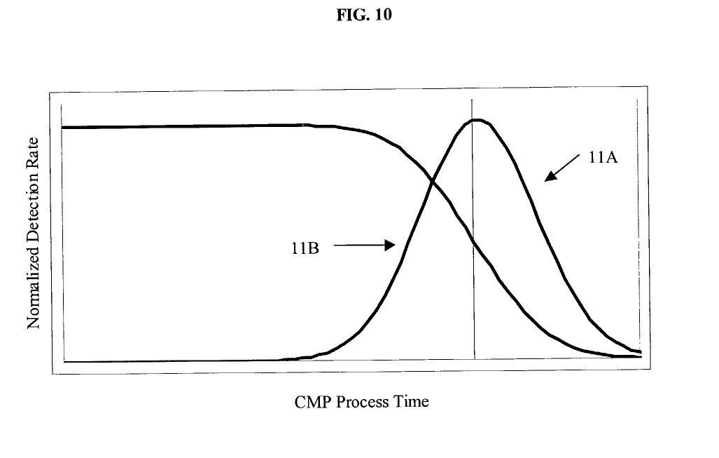

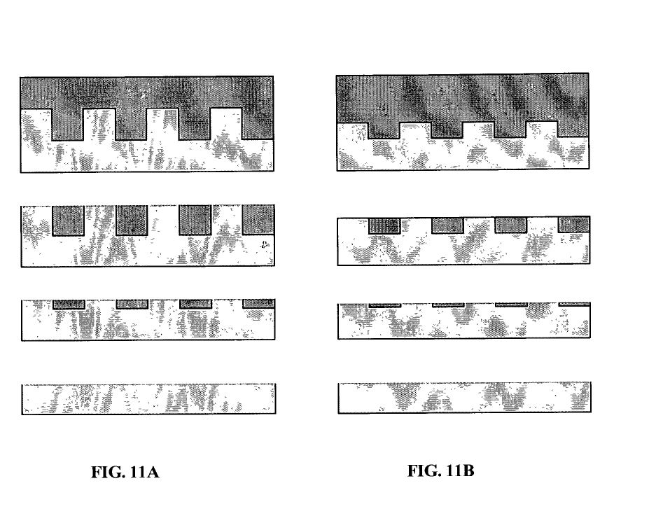

Ideally, the thicknesses and indices of refraction of the films of the target can be engineered to produce an endpoint trace best suited for the application. Examples of two possible signal traces are shown in FIG. 10 corresponding to the “half wave” and “quarter wave” grating structures illustrated in FIG. 11.

In FIG. 11A, the optical path difference (OPD) between the top and bottom of the grating is a half-wavelength, and would produce an endpoint curve similar to the curve labeled 11A in FIG. 10. The quarter wave grating shown in FIG. 11B, which has half the height of the half wave grating, produces the maximum diffracted signal before the CMP surface reaches the grating, then monotonically decreases as the surface is removed. The signal from the quarter wave grating is depicted as curve 11B in FIG. 10. In both cases, the endpoint can be determined, either by peak detection or detection of a drop by 50% in intensity.

### Example 3

### Single Grating with Different Polishing Rates

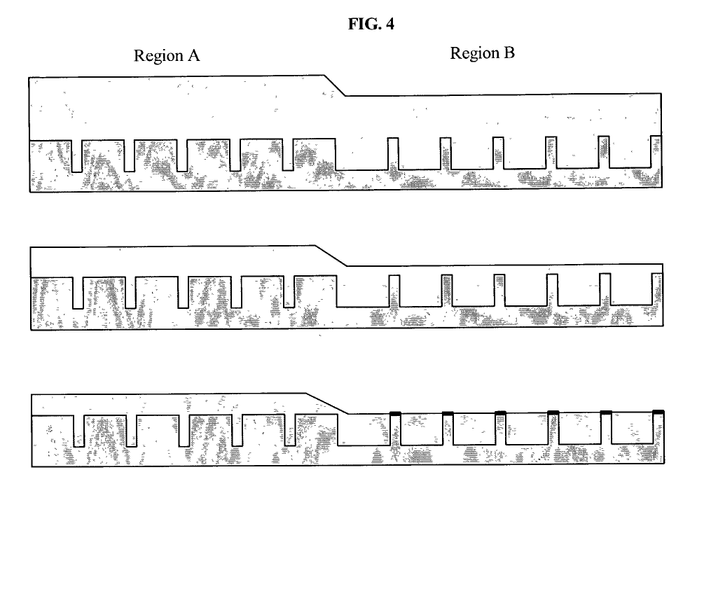

This example relates to a periodic grating providing substantially uniform diffraction across its structure but that also provides two different oxide removal rates during CMP. The grating is shown in FIG. 4. One area of the grating (region A) has a high duty cycle (wide etched trench and narrow pillars) and the other area (region B) has low duty cycle (narrow trenches that are widely separated). The amount of material in the two regions differs substantially, and after planarization of the top layer, a step height is created, as shown.

In this example, the grating has substantially uniform diffraction across its structure because the duty cycles are complementary. At moderate diffraction angles and shallow grating features, gratings with complementary duty cycles exhibits substantially the same diffraction pattern. For instance, a grating with 80% etched area will diffract a similar amount of light as a grating with 20% etched area.

Even though the regions exhibit substantially the same diffraction, because region A of the grating depicted in FIG. 4 has a higher duty cycle than region B, region A will clear slower than region B (assuming the lower layer has a slower CMP removal rate than the upper layer). This difference in CMP clearance rate between the two regions permits a two-point measurement of material removal thus allowing, for example, the region that clears earlier and therefore diffracts earlier, to function as a pre-warning of the approach of the endpoint.

It is contemplated that various modifications may be made to the endpoint detection systems of the present invention without departing from the spirit and scope of the invention as defined in the following claims.

What is claimed is:

1. A method for endpoint detection in chemical mechanical planarization of a substrate having a first layer of material and a second layer of material, wherein the second layer of material has an exposed surface that is planarized by a method comprising:
(a) placing a target at or near a location between the first layer of material and the second layer of material;
(b) planarizing the second layer of material to remove at least a portion of material from the second layer;
(c) detecting the target; and
(d) adjusting said planarizing step in response to detecting the target.

2. The method of claim 1 wherein the target is at least one periodic grating.

3. The method of claim 2 wherein the periodic grating is placed by patterning the periodic grating into said first layer of material and depositing onto said first layer said second layer.

4. The method of claim 1 wherein the first layer of material and the second layer of material are independently selected from the group consisting of metal, dielectric material and adhesive material.

5. The method of claim 2 wherein the first layer of material is a dielectric material and the second layer of material is a dielectric material.

6. The method of claim 5 wherein the first layer of material and the second layer of material have similar indices of refraction.

7. The method of claim 5 wherein the first layer of material and the second layer of material have different planarization properties.

8. The method of claim 1 wherein the target is a fluorescent compound.

9. The method of claim 8 wherein said fluorescent compound contains a trivalent lanthanide.

10. The method of claim 9 wherein said lanthanide is Eu³⁺ or Er³⁺.

11. The method of claim 8 wherein said detection step comprises detecting a change in the level of fluorescence from the substrate.

12. The method of claim 2 wherein the periodic grating has a feature size of about 0.3 to about 1.55 microns.

13. A method of chemical mechanical planarization of a wafer, comprising:
(a) placing the wafer in contact with a polishing substrate,
wherein the wafer comprises a first layer of material, a second layer of material and a target placed at or near a location between the first layer of material and the second layer of material;
(b) applying pressure against the backside of the substrate;
(c) causing relative motion between the wafer and the polishing substrate;
(d) depositing a polishing composition onto the polishing substrate;
(e) planarizing the wafer by removing material from the second layer; and
(f) adjusting the planarization step in response to detecting the target.

14. The method of claim 13 wherein the polishing substrate is a polishing pad.

15. The method of claim 14 wherein the polishing is a fixed abrasive polishing pad.

16. The method of claim 13 wherein the polishing composition includes abrasive particles.

17. The method of claim 13 wherein the target is at least one periodic grating.

18. The method of claim 17 wherein the periodic grating is placed by patterning the periodic grating into said first layer of material and depositing onto said first layer said second layer.

19. The method of claim 17 wherein the first layer of material is a dielectric material and the second layer of material is a dielectric material.

20. The method of claim 19 wherein the first layer of material and the second layer of material have similar indices of refraction.

21. The method of claim 19 wherein the first layer of material and the second layer of material have different planarization properties.

22. The method of claim 13 wherein the target is a fluorescent compound.

23. The method of claim 22 wherein the fluorescent compound is a trivalent lanthanide.

24. The method of claim 22 wherein the fluorescent compound is detected in step (f) by detecting the absence of fluorescence from the substrate.

25. The method of claim 17 wherein the grating has a feature size of about 0.3 to about 1.55 microns.

26. A substrate comprising a first layer of material, a second layer of material and a target placed at or near a location between the first layer of material and the second layer of material.

27. The substrate of claim 26 wherein the target is at least one periodic grating.

28. The substrate of claim 27 wherein the periodic grating is placed by patterning a periodic grating into said first layer of material and depositing onto said first layer said second layer.

29. The substrate of claim 27 wherein the first layer of material is a dielectric material and the second layer of material is a dielectric material.

30. The substrate of claim 29 wherein the first layer of material and the second layer of material have similar indices of refraction.

31. The substrate of claim 29 wherein the first layer of material and the second layer of material have different planarization properties.

32. The substrate of claim 26 wherein the target is a fluorescent compound.

33. The substrate of claim 26 wherein the fluorescent compound contains a trivalent lanthanide.

34. The substrate of claim 33 wherein said lanthanide is Eu³⁺ +or Er³⁺.

35. The substrate of claim 27 wherein the grating has a feature size of about 0.3 to about 1.55 microns.

36. A method of detecting an event during chemical mechanical planarization of a substrate having a lower layer of material and an upper layer of material, comprising:
placing a first target having a first distinguishable characteristic at or near a first event on the substrate, wherein the first target is encoded for the first event;
placing a second target having a second distinguishable characteristic at or near a second event on the substrate, wherein the second target is encoded for the second event;
planarizing the upper layer of material to remove at least a portion of material from the upper layer;
observing the first or second target; and
adjusting the planarization step in response to observing the first or second target.

37. The method of claim 36 wherein said observation step comprises passing the first and second targets through a field of view of an optical detection system, wherein the optical detection system is tuned to distinguish the first and second targets based on the distinguishable characteristic of the targets.

38. The method of claim 37 wherein the first target is a periodic grating and the second target is a periodic grating.

39. The method of claim 38 wherein the distinguishable characteristic of the first grating is pitch size and the distinguishable characteristic of the second grating is pitch size.

40. The method of claim 39 wherein the pitch size of the first grating is different from the pitch size of the second grating.

41. The method of claim 40 wherein the pitch size of the first grating is in the range of about 0.5 to 3 microns and the pitch size of the second grating is in the range of about 0.5 to 3 microns.

42. The method of claim 38 wherein the distinguishable characteristic of the first grating is orientation and the distinguishable characteristic of the second grating is orientation.

43. The method of claim 42 wherein the orientation of the first grating is different from the orientation of the second grating.

44. The method of claim 43 wherein the first grating is rotated by about 90 degrees relative to the second grating.

45. The method of claim 36 wherein the first event is a region of high pattern density.

46. The method of claim 36 wherein the second event is a region of low pattern density.
